(19) United States
(12) Patent Application Publication
(10) Pub. No.: US 2004/0194303 A1
(43) Pub. Date: Oct. 7, 2004

(54) Method of fabricating multi-layered printed circuit board

(75) Inventors: Eung-Soo Kim, Chungcheongbuk-do (KR); Jang-Kyu Kang, Daejeon (KR); Jee-Soo Mok, Chungcheongbuk-do (KR); John-Tae Lee, Daejeon (KR); Chang-Kyu Song, Daejeon (KR); Byung-Kook Sun, Seoul (KR)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: Samsung Electro-Mechanics Co., Ltd.

(21) Appl. No.: 10/677,601

(22) Filed: Oct. 2, 2003

(30) Foreign Application Priority Data
Apr. 2, 2003 (KR) 2003-20761

(51) Int. Cl. H05K 3/02

(52) U.S. Cl. 29/852; 29/847; 29/831; 156/307.7

(57) ABSTRACT

Disclosed is a method of fabricating a multi-layered PCB, wherein a plurality of circuit layers on which circuit patterns are constructed and insulating layers which are alternately positioned between the circuit layers to insulate the circuit layers from each other are severally fabricated according to different processes, and then layered with each other at once.

The present invention provides a method of fabricating a multi-layered PCB, in which a copper clad laminate is drilled to create via holes therethrough in such a way that a diameter of each via hole is relatively small, and then plated with copper to plug the via holes with the copper, thereby omitting the plugging process of the via holes using paste. The insulating layers are formed in such a way that semi-hardened (b-stage) thermosetting resin layers are layered on both sides of a completely hardened (C-stage) thermosetting resin layer, thereby improving impedance balance of the insulating layer.

### BACKGROUND OF THE INVENTION

1. Field of the Invention

The present invention pertains, in general, to a method of fabricating a multi-layered printed circuit board (MLB). More particularly, the present invention relates to a method of fabricating a multi-layered printed circuit board, wherein a plurality of circuit layers on which circuit patterns are constructed and insulating layers which are alternately positioned between the circuit layers to insulate the circuit layers from each other are severally fabricated according to different processes, and then layered with each other at once, unlike a conventional build-up process.

2. Description of the Prior Art

As well known to those skilled in the art, demand for fine-patterned, small-sized, and packaged printed circuit board (PCB) are growing with the recent trend toward small, slim, highly integrated, packaged, and portable electronic goods. Further, conventional substances for constituting a multi-layered PCB are being replaced and the number of layers constituting the MLB is increasing so as to form a fine-pattern on the MLB, secure reliability of the MLB, and improve a design density of the MLB. As for electronic parts, a dual in line package (DIP) type of electronic parts is apt to be replaced with a surface mount technology (SMT) type of electronic parts, so a mount density on the electronic parts is gradually increased. Furthermore, there remains a need to secure a sophisticated technology for designing a complicated PCB because it is needed for the recent portable and multi-purpose electronic goods to function to transceive moving pictures and large-sized data on-line.

The PCB is classified into three types according to the number of layers constituting the PCB: a single-sided PCB in which a wire is formed on only one side of an insulating layer, a double-sided PCB in which wires are formed on both sides of the insulating layer, and a multi-layered board (MLB) in which wires are formed on multiple layers. Conventionally, the single-sided PCB was most popular because electronic parts generally have simple structures and their circuit patterns are not complicated. However, recently, the double-sided PCB or MLB is frequently being used in accordance with the increasing need for highly integrated, complicated, and fine circuit patterns. In the present invention, there is described a method of fabricating the MLB.

The MLB is the PCB including layers on which a circuit pattern is capable of being constructed so as to enlarge a circuit pattern area. In detail, the MLB comprises inner and outer layers, and the inner layers each include a thin core (T/C). Traditionally, the base MLB is a four-layered PCB consisting of two inner layers and two outer layers attached to the inner layers using a prepreg. Accordingly, it should be understood that the term MLB as used herein is intended to include the PCB consisting of at least four layers. The MLB may alternatively include six, eight, and ten layers.

An electric source circuit pattern, a grounding circuit pattern, and a signal circuit pattern may be constructed on the inner layers, and the prepreg positioned between the inner layer and outer layer, or between the outer layers functioning to insulate the layers from each other and to attach the layers to each other. At this time, the circuit patterns on layers are electrically connected to each other through via holes (through holes).

The MLB can have a desirably increased wiring density, but is disadvantageous in that its fabricating process is very complicated due to the increased wiring density. Particularly, if the inner layers fabricated according to a conventional build-up process cannot be repaired during fabricating the MLB even though it is found that the inner layers have defective portions, the MLB having the defective inner layers should be discarded. To avoid these disadvantages, various inspection devices are used to detect damage of the inner layers.

In order to better understand the background of the present invention, a description will be given of the fabrication of the MLB according to the conventional build-up process, below.

FIGS. 1A to 1M are sectional views stepwisely illustrating the fabrication of a six-layered PCB according to the conventional build-up process. In the present specification and claims, the term “build-up process” means a process comprising fabricating inner layers, and layering outer layers one by one on the inner layers after the inner layers are fabricated.

With reference to FIG. 1A, there is illustrated a sectional view of an unprocessed copper clad laminate (CCL) 101. At this time, the copper clad laminate 101 consists of an insulating layer 103 and copper foil 102 thinly coated on both sides of the insulating layer 103, and acts as a base substrate of the PCB.

The copper clad laminate 101 is classified into a glass/epoxy-copper clad laminate, a heat-resistant resin copper clad laminate, paper/phenol-copper clad laminate, a high-frequency copper clad laminate, a flexible copper clad laminate (polyimide film), and a complex copper clad laminate in accordance with its use. Among the above, the glass/epoxy-copper clad laminate is mostly used to fabricate a double-sided PCB and the multi-layered PCB.

At this time, the glass/epoxy copper clad laminate consists of a reinforced base substrate in which epoxy resin including a curing agent is penetrated into a glass fiber, and copper foil coated on the reinforced base substrate. Furthermore, the glass/epoxy copper clad laminate is graded FR-1 to FR-5, as prescribed by the National Electrical Manufacturers Association (NEMA), in accordance with a kind of the reinforced base substrate and heat resistance. Traditionally, the FR-4 grade of glass/epoxy copper clad laminate is mostly used, but in recent, demands for the FR-5 grade of glass/epoxy copper clad laminate which is growing in terms of improved glass transition temperature (T_{g}) is growing.

Referring to FIG. 1B, the copper clad laminate 101 is drilled to form a via hole 104 for connecting circuit patterns of each circuit layer to each other.

Turning to FIG. 1C, an electroless-copper plating and an electrolytic-copper plating process are conducted. In this regard, the electroless-copper plating process is conducted before the electrolytic-copper plating process. The reason that the electroless-copper plating process is conducted before the electrolytic-copper plating process is that the electrolytic-copper plating process using electricity is not accomplished on the insulating layer. In other words, the electroless-copper plating process is conducted as a pretreatment process to form a thin conductive film needed to conduct the electrolytic-copper plating process on the CCL. Furthermore, it is preferable that conductive parts of the circuit patterns are formed by the electrolytic-copper plating process, because it is difficult to conduct the electroless-copper plating process, and economic efficiency of the electroless-copper plating process is poor.

After the completion of the electroless-copper plating and electrolytic-copper plating process, paste 106 is plugged in the via hole 104 so as to protect the electroless and electrolytic copper-plated layer 105 formed on the wall of the via hole 104. The paste 106 generally consists of insulating ink materials, but may consist of conductive paste according to the purpose in use of the PCB. The conductive paste may include only a metal mostly consisting of Cu, Ag, Au, Sn, or Pb, or a mixture of the metal and an organic adhesive. However, the plugging process of the via hole 104 using the paste may be omitted according to the purpose of the MLB.

In FIG. 1C, electroless and electrolytic copper-plated layer are illustrated as one layer without distinguishing two layers from each other.

An etching resist pattern 107 for forming an inner circuit pattern is then constructed on the copper-plated layer 105, as shown in FIG. 1D.

At this time, a circuit pattern printed on an artwork film should be transferred onto a substrate so as to construct the etching resist pattern 107. There are various methods of transferring the circuit pattern onto the substrate, but a method of transferring the circuit pattern printed on the artwork film to a photosensitive dry film using ultraviolet rays is most frequently used. In this regard, recently, a liquid photo resist (LPR) is used instead of the photosensitive dry film.

The dry film or LPR to which the circuit pattern is transferred acts as the etching resist 107, and the circuit pattern is constructed on the substrate when the substrate is dipped in an etching liquid as shown in FIG. 1E.

After the construction of the circuit pattern on the substrate, appearance of the circuit pattern is observed using an automatic optical inspection (AOI) device so as to evaluate whether the inner circuit is desirably formed or not, and the resulting substrate is subjected to a surface treatment such as a black oxide treatment.

The AOI device is used to inspect appearance of the PCB by an image sensor and a pattern recognition technology using a computer. In detail, after reading information about the circuit pattern using the image sensor, the AOI device compares the information with reference data to evaluate whether the circuit pattern is desirably constructed or not.

Using the AOI device, the minimum value of an annular ring of a land (a portion of the PCB, on which parts are mounted) and a grounding state of the electric source can be inspected. Furthermore, a width of the circuit pattern can be measured and it can be evaluated whether the via hole is formed or not. However, it is impossible to inspect an inside of the via hole using the AOI device.

Meanwhile, the black oxide treatment is conducted so as to increase an adhering force and heat resistance of the circuit patterns before the inner layer having circuit patterns is attached to a first outer layer.

Referring to FIG. 1F, a first resin-coated copper (RCC) is layered on both sides of the resulting copper clad laminate. The first RCC consists of a substrate including a copper foil layer 109 layered on only one side of a resin layer 108, and the resin layer 108 acts as an insulating body.

In FIG. 1G, a first blind via hole 110 for electrically connect the inner layer to the first outer layer is created through the resulting copper clad laminate. The first blind via hole 110 may be created using a mechanical drill, but it is preferable to use an yttrium aluminum garnet (YAG) laser beam or CO₂ laser beam instead of the mechanical drill so as to precisely create the first blind via hole 110. The YAG laser beam is used to drill both the copper foil layer 109 and insulating layer, but the CO₂ laser beam is used to drill only the insulating layer.

The first outer layer 111 is then layered on the resulting copper clad laminate according to a plating process as shown in FIG. 1H.

As in FIG. 1I, the first outer layer 111 is patterned according to the same procedure as the construction of the circuit pattern of the inner layer. The patterned outer layer 111 is then inspected and subjected to a surface treatment.

Referring to FIG. 1J, a second RCC is layered on the first outer layer 111 so as to additionally layer a second outer layer 115 on the first outer layer. The second RCC includes a resin layer 112 and a copper foil layer 113 coated on one side of the resin layer 112, and the resin layer 112 acts as the insulating body.

Like the case of the first blind via hole 110, a second blind via hole 114 is formed for electrically connecting outer layers to each other using the laser beam as shown in FIG. 1K.

In FIG. 1L, the second outer layer 115 is additionally layered on the copper foil layer 113 according to a plating process.

Turning to FIG. 1M, the second outer layer 115 is patterned in the same procedure as the case of the first outer layer 111, and the patterned second outer layer 115 is then inspected and subjected to a surface treatment.

The number of layers constituting the multi-layered PCB may be continuously increased by repeating the layering of an additional layer, the construction of the circuit pattern, the inspection of the circuit pattern, and the surface treatment of the resulting structure.

A photo-solder resist (PSR) and a Ni/Au layer are plated on the resulting circuit pattern, thereby accomplishing the six-layered MLB.

In detail, when a photo-solder resist pattern is formed on a portion of the MLB, on which other substrates or chips are not mounted, and the Ni/Au layer is plated on the photo-solder resist pattern, the photo-solder resist pattern acts as a plating resist, thus plating the Ni/Au layer on a portion of the MLB, on which other substrates or chips are mounted. At this time, Ni is firstly plated, and Au is then plated on the MLB. The plating of the Ni/Au layer on the photo-solder resist pattern is a step which ends the fabrication process of the MLB, thereby preventing an exposed copper foil portion not covered with the solder resist from oxidizing, improving solderability of electronic parts mounted on the MLB, and providing excellent conductivity to the MLB.

However, a conventional method of fabricating a PCB has a limit in coping with the recent trend of miniaturization and slimness of the electronic goods, and is insufficiently competitive in terms of fabrication cost when the multipurpose PCB is fabricated according to the conventional method. Meanwhile, currently, the selling price of the electronic parts is falling, and the great advances in the electronic parts industry contribute to shortening a fabrication period of them.

With respect to the above recent trend, a conventional method of fabricating the MLB using the build-up process is insufficiently competitive in terms of fabrication cost and time, in which the via holes are created through the substrate using a laser beam, walls of the via holes are plated with a desirable metal so as to electrically connect circuit patterns of each layer, and the resulting substrates are layered each other.

That is to say, the conventional build-up process is disadvantageous in that when the number of layers constituting the MLB is increased, the procedure of creating via holes using the laser beam, the layering procedure of the layers, and the plating procedure are sequentially repeated to prolong fabrication time of the MLB, and it is difficult to inspect the MLB during the fabrication of the desired MLB, thus undesirably increasing the defective proportion of the MLB to increase fabrication cost of the MLB.

Additionally, the conventional method, in which the via holes are created in the MLB, the walls of the via holes are plated with copper, and the via holes are plugged with paste to protect the copper-plated layer on the via holes, is disadvantageous in that the plugging process of the via holes using the paste is additionally conducted after the walls of the via holes are plated with copper.

Another disadvantage of the conventional method is that the insulating layer consisting of dielectric resin has a higher impedance than the circuit layer. Affecting a circuit pattern, an impedance value of the insulating layer depends on thickness variation of the insulating layer, and physical properties of the dielectric resin, that is, dielectric constant, mass, or volume of the dielectric resin. Hence, there remains a need to develop a method of easily controlling the impedance value of the insulating layer.

### SUMMARY OF THE INVENTION

Therefore, the present invention has been made keeping in mind the above problems occurring in the prior art, and an object of the present invention is to severally form circuit layers and insulating layers according to different processes and alternately layer them at one time to reduce fabrication cost and time of MLB, and minimize the defective proportion of the MLB by the inspection of a circuit pattern before the circuit and insulating layers are layered.

It is another object of the present invention to provide a method of fabricating a multi-layered PCB, in which a copper clad laminate is drilled to create via holes therethrough in such a way that a diameter of each via hole is relatively small during forming a circuit layer, and then plated with copper to plug the via holes with the copper, thereby omitting the plugging process of the via holes using paste.

It is still another object of the present invention to provide a method of fabricating a multi-layered PCB, in which an insulating layer is formed in such a way that semi-hardened (b-stage) thermosetting resin layers are layered on both sides of a completely hardened (c-stage) thermosetting resin layer, thereby improving workability, allowing the insulating layer to have high specific dielectric property, and improving impedance balance of the insulating layer.

Based on the present invention, the above objects can be accomplished by providing a method of fabricating multi-layered printed circuit board, including forming a plurality of circuit layers, forming insulating layers before or after the circuit layers are formed, and alternately layering the circuit layers and insulating layers while compressing them.

### BRIEF DESCRIPTION OF THE DRAWINGS

The above and other objects, features and other advantages of the present invention will be more clearly understood from the following detailed description taken in conjunction with the accompanying drawings, in which:

FIGS. 1A to 1M are sectional views stepwisely illustrating the fabrication procedure of a multi-layered PCB according to a conventional build-up process;

FIGS. 2A to 2E are sectional views stepwisely illustrating the fabrication of a circuit layer constituting a multi-layered PCB, according to a first embodiment of the present invention, the fabrication process being performed according to a conventional technology;

FIGS. 3A to 3D are sectional views stepwisely illustrating the fabrication of a circuit layer constituting a multi-layered PCB according to a second embodiment of the present invention, in which fine via holes of a copper clad laminate are plugged by plating the copper clad laminate with copper;

FIGS. 4A to 4D are sectional views stepwisely illustrating the fabrication of a circuit layer constituting a multi-layered PCB according to a third embodiment of the present invention, in which via holes are plugged by conductive paste;

FIGS. 5A to 5D are sectional views stepwisely illustrating the fabrication of an insulating layer constituting a multi-layered PCB, according to an embodiment of the present invention, the fabrication process being performed according to a conventional technology;

FIGS. 6A to 6D are sectional views stepwisely illustrating the fabrication of an insulating layer constituting a multi-layered PCB according to another embodiment of the present invention, in which the insulating layer includes semi-hardened resin;

FIG. 7 illustrates the layering process of circuit layers and insulating layers according to the present invention; and

FIG. 8 is a sectional view of a six-layered PCB fabricated according to the present invention.

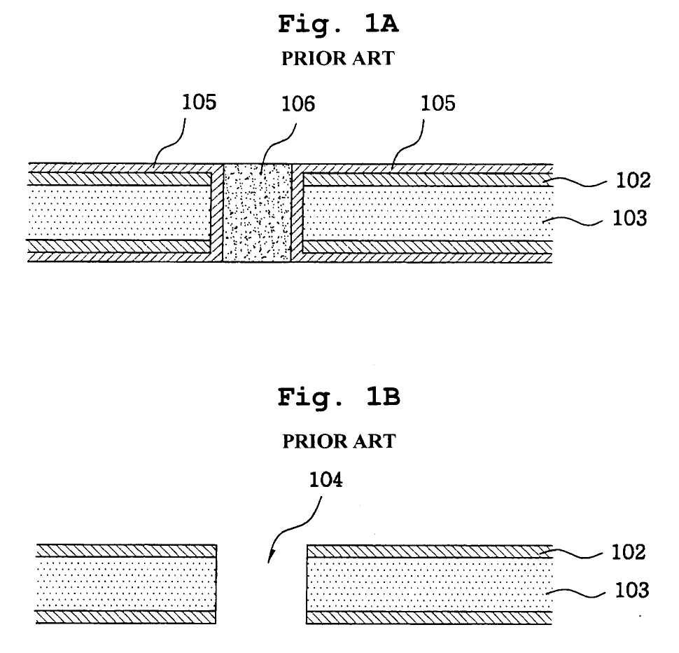

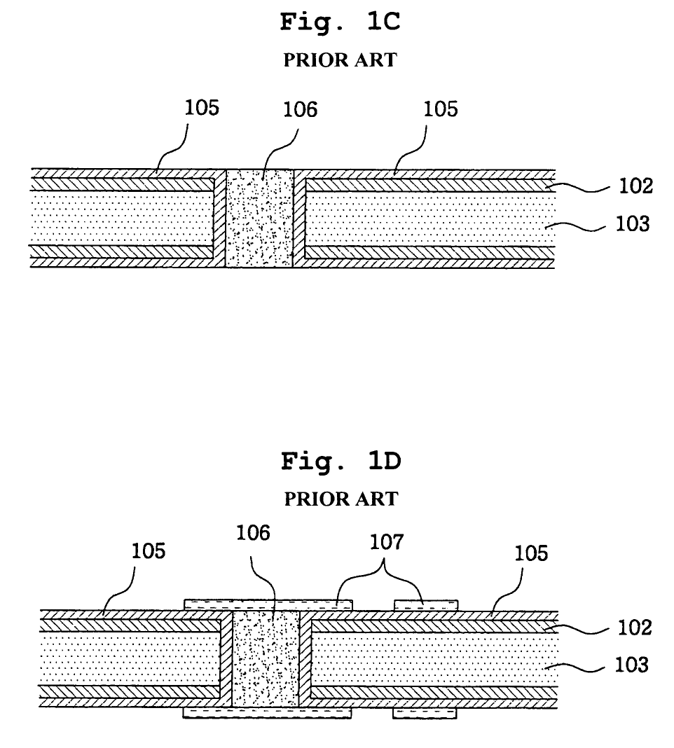

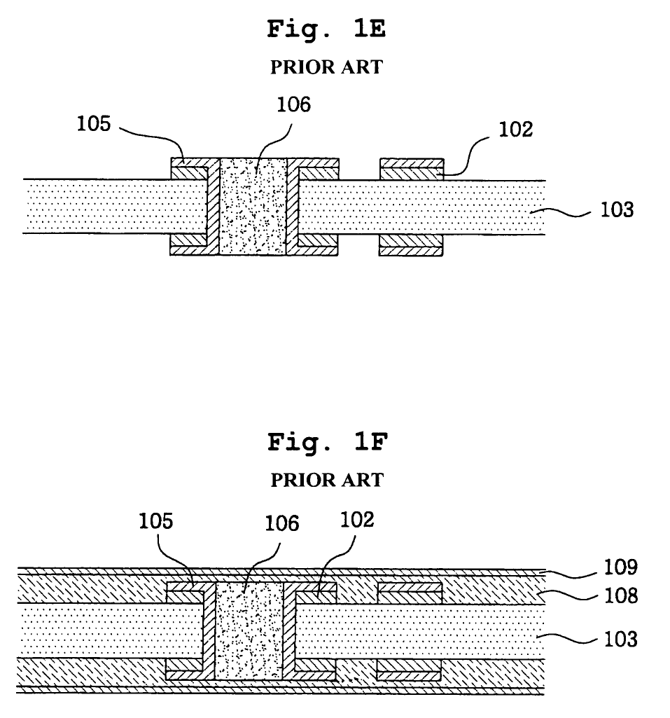

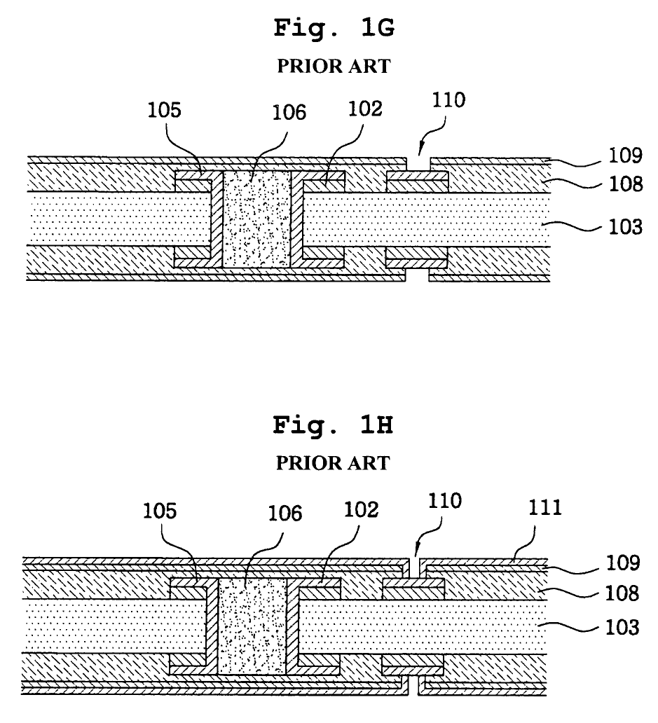

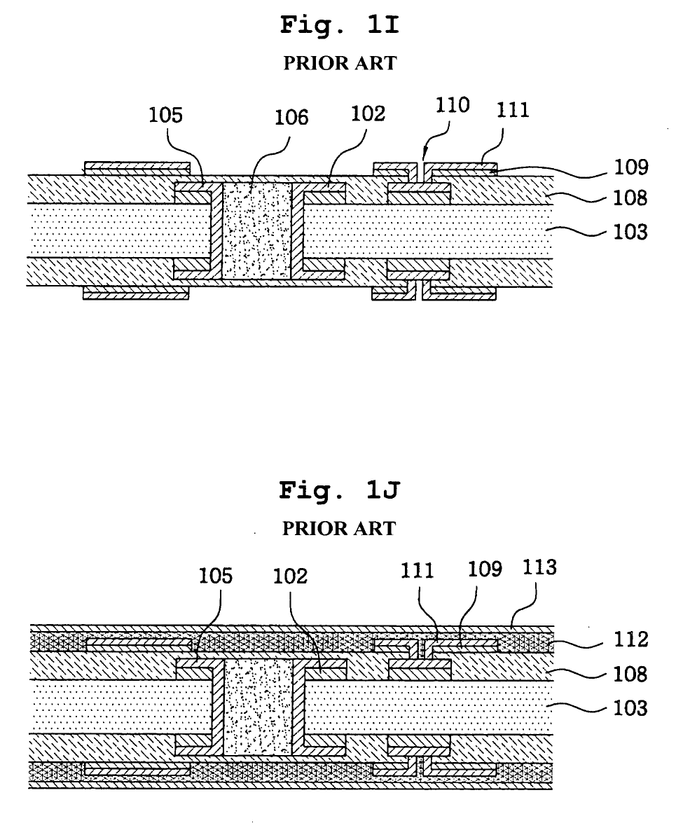

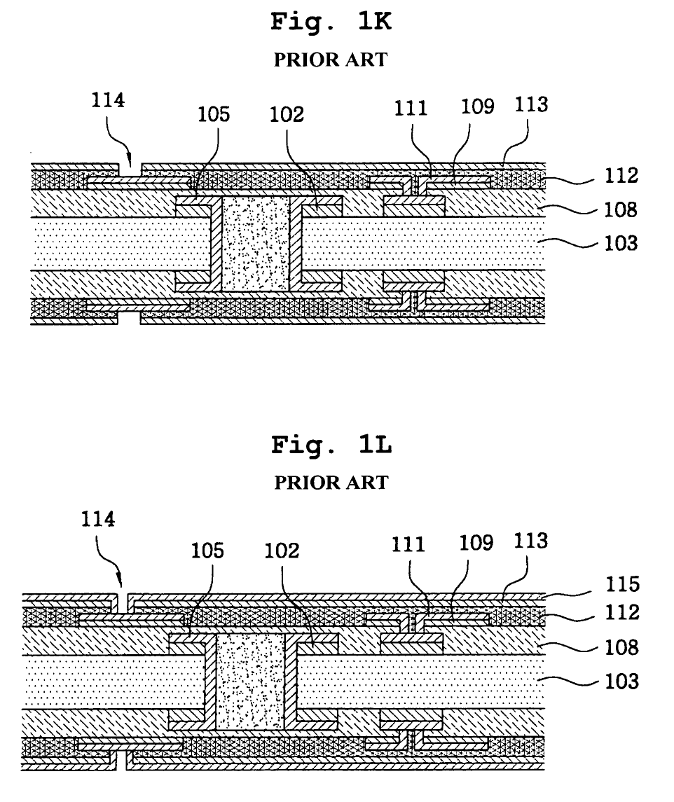

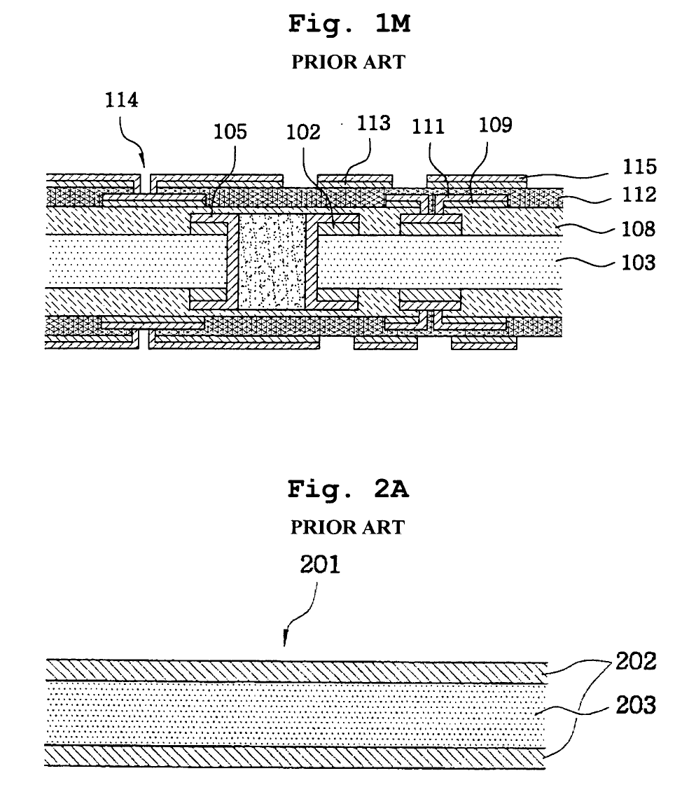

### DETAILED DESCRIPTION OF THE INVENTION

Reference now should be made to the drawings, in which the same reference numerals are used throughout the different drawings to designate the same or similar components.

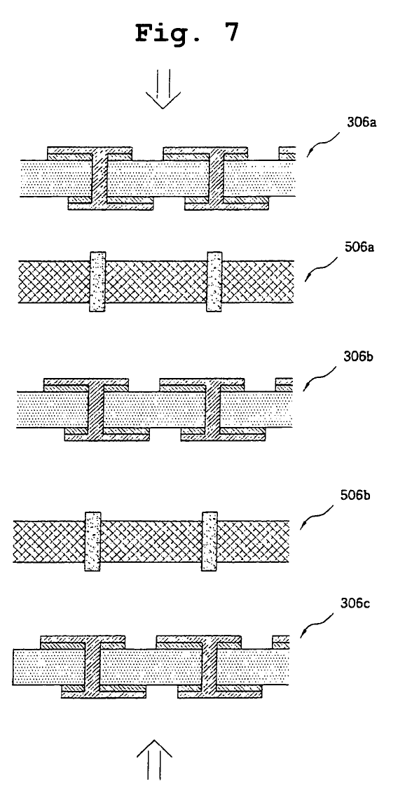

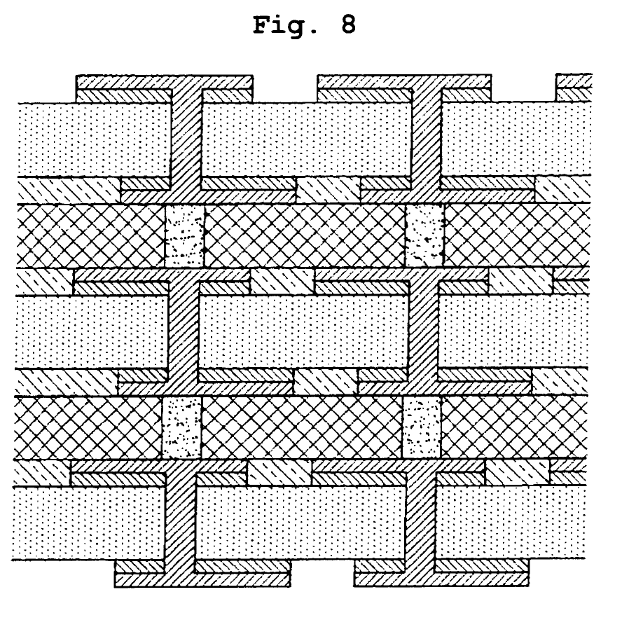

FIG. 7 illustrates the layering process of circuit layers and insulating layers. The circuit layers 306a, 306b, 306c and insulating layers 506a, 506b are severally formed according to different processes, arranged in such a way that the circuit layers and insulating layers are alternately layered as shown in FIG. 7, and then compressed to make them come into contact with each other to fabricate a six-layered PCB as shown in FIG. 8.

Now, there will be given a description of different processes of fabricating the circuit layers and the insulating layers, below.

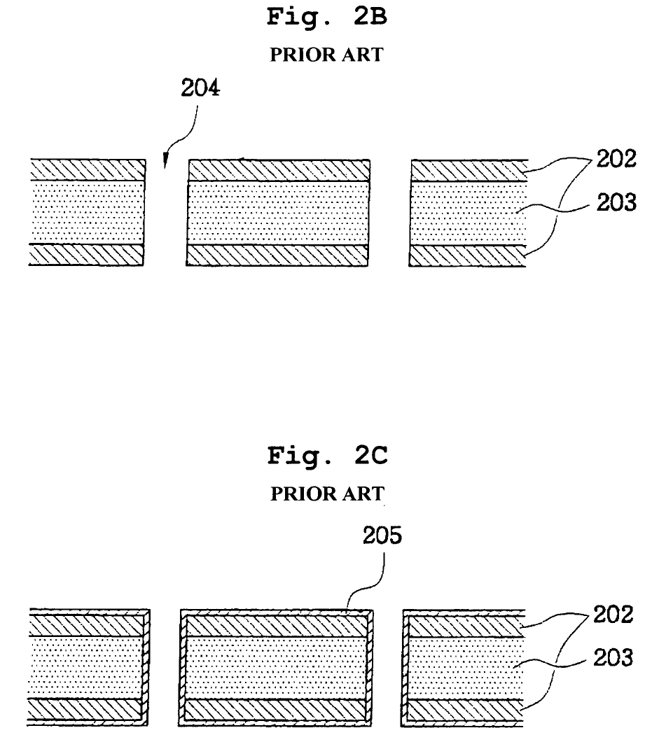

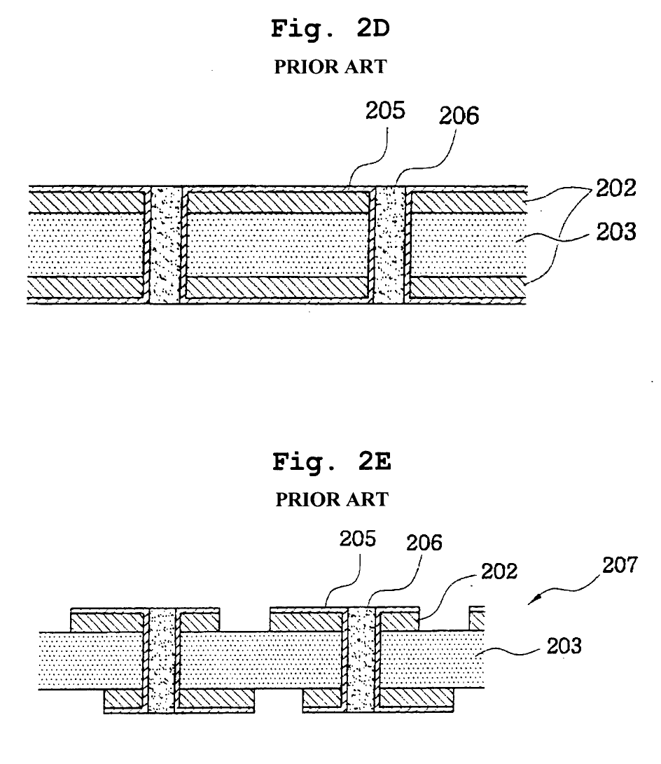

FIGS. 2A to 2E are sectional views stepwisely showing the fabrication of a circuit layer constituting a multi-layered PCB, according to a first embodiment of the present invention, the fabrication process being performed according to a conventional technology.

With reference to FIG. 2A, there is illustrated a copper clad laminate 201 consisting of an insulating layer 203 with its both sides coated with copper foil 202.

The copper clad laminate 201 is drilled to create via holes 204 therethrough as shown in FIG. 2B.

Referring to FIG. 2C, the copper clad laminate is then subjected to an electroless-copper plating and an electrolytic-copper plating process to form a conductive layer 205 on the copper clad laminate 201.

Turning to FIG. 2D, the via holes 204 are plugged with paste 206 so as to protect themselves. The paste 306 may consist of an insulating ink material or a conductive material. Additionally, the plugging process of the via holes 204 using the paste 206 may be omitted in accordance with a purpose of the multi-layered PCB.

The resulting copper clad laminate is then subjected to a traditional circuit patterning process such as an etching process, thereby accomplishing the circuit layer as shown in FIG. 2E.

The circuit layer of FIG. 2E may be used as one of the circuit layers 306a, 306b, 306c of FIG. 7 according to the present invention. In this regard, correct position and dimension of circuit patterns on the circuit layers must be planned in advance in consideration of layering of the circuit layers and the insulating layers.

Furthermore, the number of the circuit layers in the multi-layered PCB depends on the total number of layers constituting the multi-layered PCB. For example, the two circuit layers are needed in a four-layered PCB. Likewise, the three and four circuit layers are needed in a six- and eight-layered PCB, respectively.

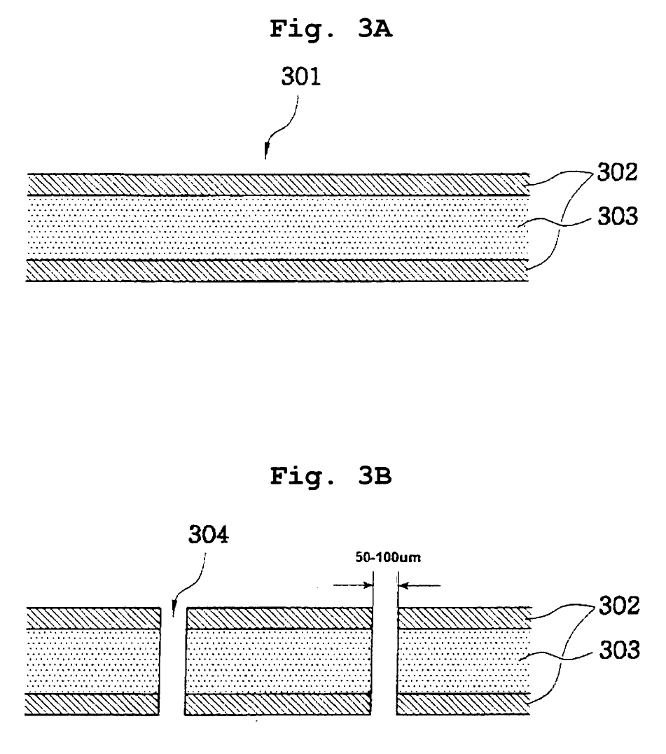

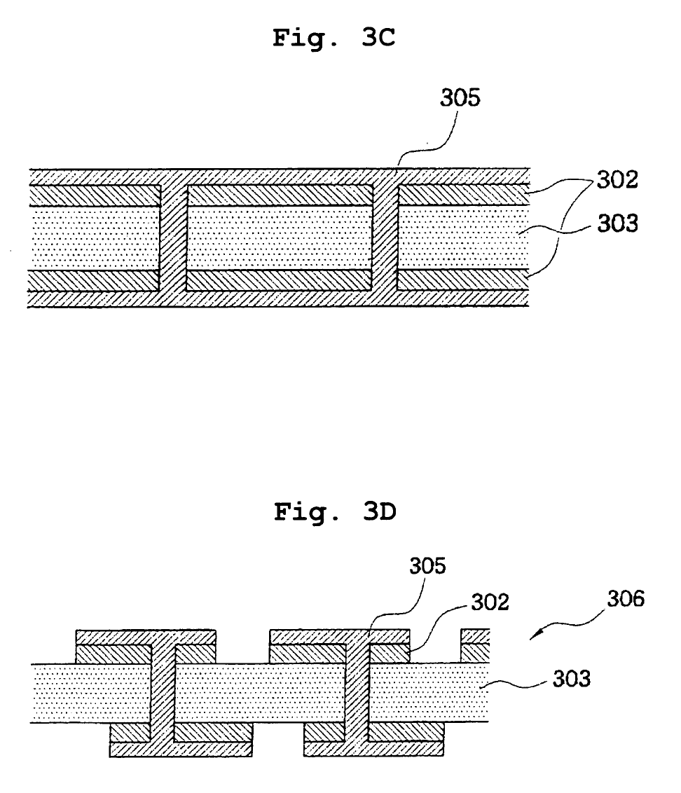

FIGS. 3A to 3D are sectional views stepwisely showing the fabrication of a circuit layer constituting a multi-layered PCB according to a second embodiment of the present invention, in which via holes of a copper clad laminate 301 are plugged by plating the copper clad laminate with copper.

Referring to FIG. 3A, there is illustrated the copper clad laminate 301 consisting of an insulating layer 303 with its both sides coated with copper foil 302.

There are many kinds of copper clad laminate, but the copper clad laminate having the thin copper foil with a thickness of 3 to 5 μm is useful to fabricate the circuit layer 306. The reason for this is that the copper clad laminate is drilled by a laser drill or a mechanical drill to create fine via holes with a relatively small diameter. That is to say, the copper foil must be thin because the via holes with small diameter are created through the copper clad laminate.

As in FIG. 3B, the via holes 304 are created through the copper clad laminate 301 so that their diameters each are 50 to 100 μm using a YAG laser beam or a CO₂ laser beam. The diameter of each via hole 304 is relatively small in comparison with a traditional via hole with diameter ranging from 200 to 300 μm, so the plugging process of the via hole using paste may be omitted in the fabrication of the circuit layer 306.

Turning to FIG. 3C, the copper clad laminate in which the via holes 304 are created is subjected to an electroless-copper plating and an electrolytic-copper plating process to plate both sides of the copper clad laminate and walls of the via holes with copper. Thereby, plated layers 305 are formed on both sides of the copper clad laminate 301, and the via holes 304 are plugged by copper.

According to the conventional process as shown in FIGS. 2A to 2E, the via holes need to be plugged with the insulating in material after the copper clad laminate is subjected to the electroless-copper plating and electrolytic-copper plating process to plate walls of the via holes. On the other hand, the via holes 304 are created in such a way that their diameters are relatively small, and the via holes 304 are plugged by the electroless-copper plating and electrolytic-copper plating, and thus do not need to be subjected to any additional plugging process.

Accordingly, the plugging process of the via holes of the copper clad laminate using the paste may be omitted even though it is necessary to plug the via holes in accordance with a purpose of the multi-layered PCB.

The resulting copper clad laminate plated with copper is then subjected to a traditional circuit patterning process such as an etching process, thereby accomplishing the circuit layer as shown in FIG. 3D. The circuit layer may be used as one of the circuit layers 306a, 306b, 306c of FIG. 7 according to the present invention.

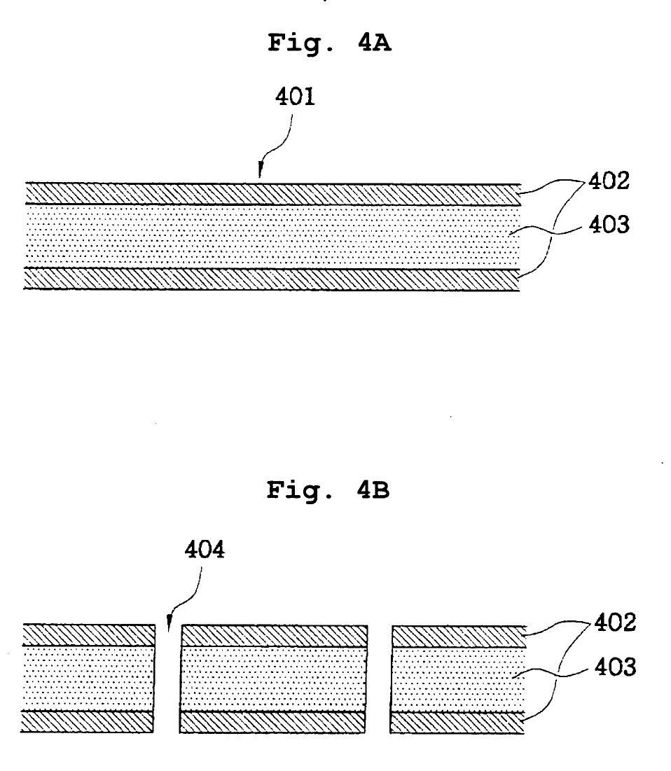

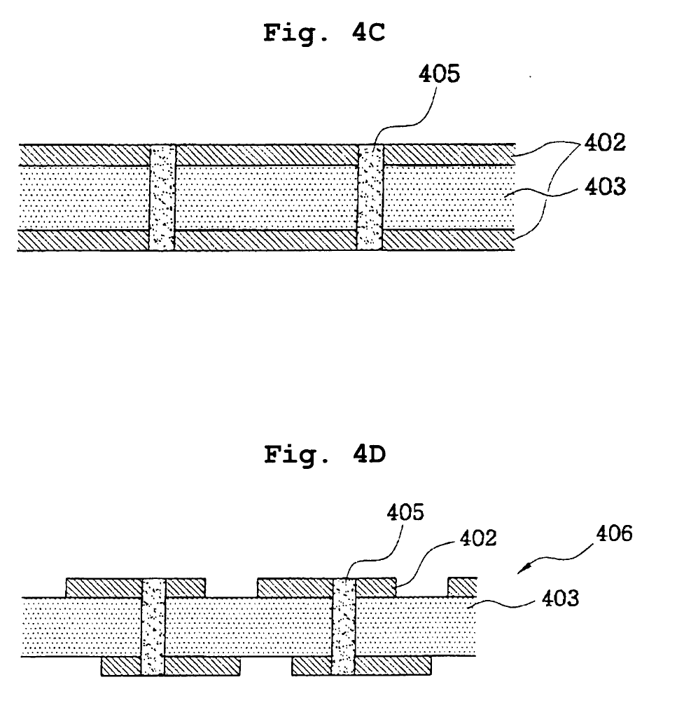

FIGS. 4A to 4D are sectional views stepwisely showing the fabrication of a circuit layer constituting a multi-layered PCB according to a third embodiment of the present invention, in which via holes are plugged by conductive paste.

Referring to FIG. 4A, there is illustrated a copper clad laminate 401 consisting of an insulating layer 403 with its both sides coated with copper foil 402.

The copper clad laminate 401 is drilled to create via holes 404 therethrough as shown in FIG. 4B.

As in FIG. 4C, the via holes 404 of the copper clad laminate 401 are then plugged with the conductive paste 405.

The resulting copper clad laminate 401 is then subjected to a traditional circuit patterning process such as an etching process, thereby accomplishing the circuit layer 406 without the plating process of the copper clad laminate as shown in FIG. 4D, unlike the circuit layer 306.

Like the circuit layer 306, the circuit layer 406 may be used as one of the circuit layers 306a, 306b, 306c of FIG. 7 according to the present invention.

After fabricated according to three procedures of FIGS. 2A to 2E, FIGS. 3A to 3D, and FIGS. 4A to 4D, the circuit layers are subjected to a circuit inspection process using an AOI device and a surface treatment process.

Hereinafter, there will be given a description of the different processes of fabricating the insulating layers constituting the multi-layered PCB, below.

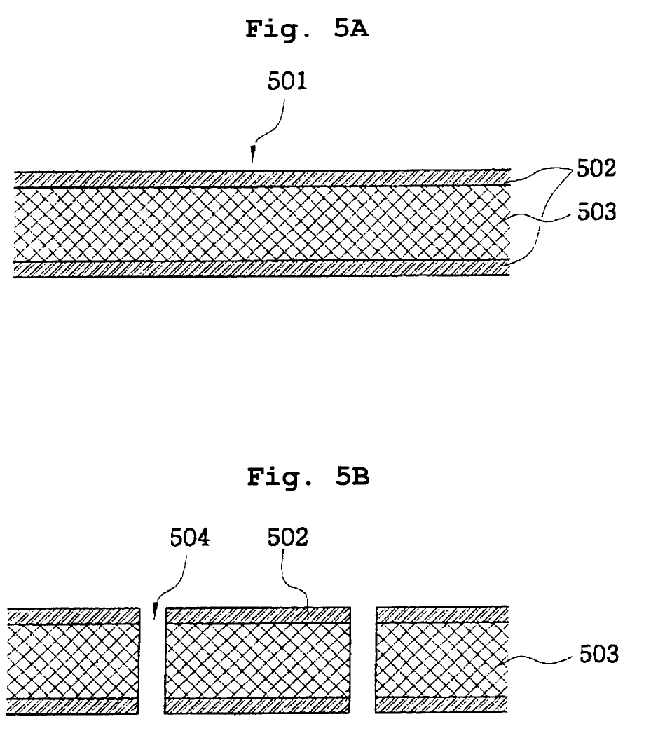

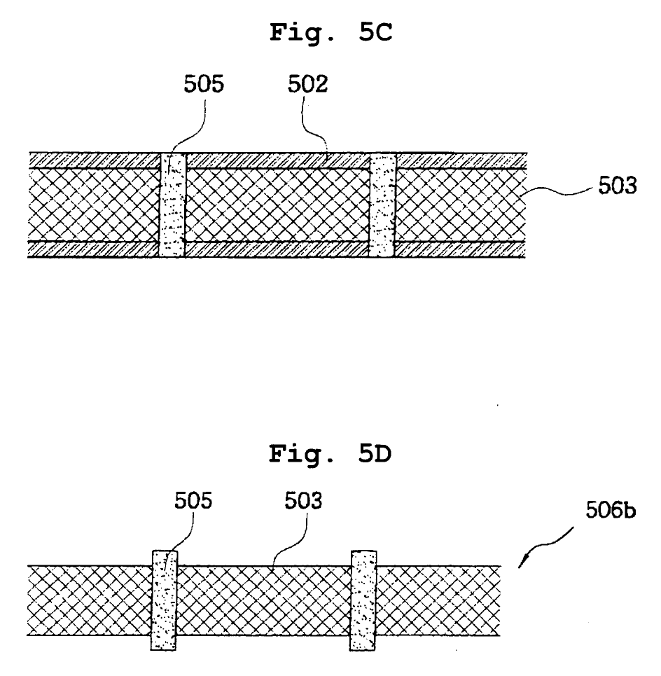

FIGS. 5A to 5D are sectional views stepwisely showing the fabrication of an insulating layer constituting the multi-layered PCB, according to an embodiment of the present invention, the fabrication process being performed according to a conventional technology.

Referring to FIG. 5A, there is illustrated an insulating layer 501 consisting of a prepreg 503 and release films 502 attached to both sides of the prepreg 503. A thickness of the prepreg 503 depends on a kind of the multi-layered PCB, and a thickness of each release film 502 is 20 to 30 μm. At this time, the release films 502 may be stuck to the prepreg 503 during the production of the prepreg 503, or the release films 502 may be attached to the prepreg 503 during the production of the insulating layer 501.

The insulating layer 501 is drilled to create openings 504 therethrough as shown in FIG. 5B. In this regard, it is preferable that the openings 504 are created by a mechanical drill, and a diameter of each opening 504 is slightly larger than that of the via hole of the circuit layer in consideration of layering of the circuit layers and the insulating layers. For example, when the insulating layer comes into contact with the circuit layer, in which the fine via holes are plugged with copper according to the plating process, fabricated by the procedure of FIGS. 3A to 3D, the insulating layer is drilled to create the openings with a diameter of about 100 μm.

Turning to FIG. 5C, the openings 504 are plugged with paste 505. The release films 502 are then removed from the insulating layer 501 as shown in FIG. 5D, thereby accomplishing the insulating layer 506.

The insulating layer 506 may be used as one of the insulating layers 607a, 607b of FIG. 7 according to the present invention.

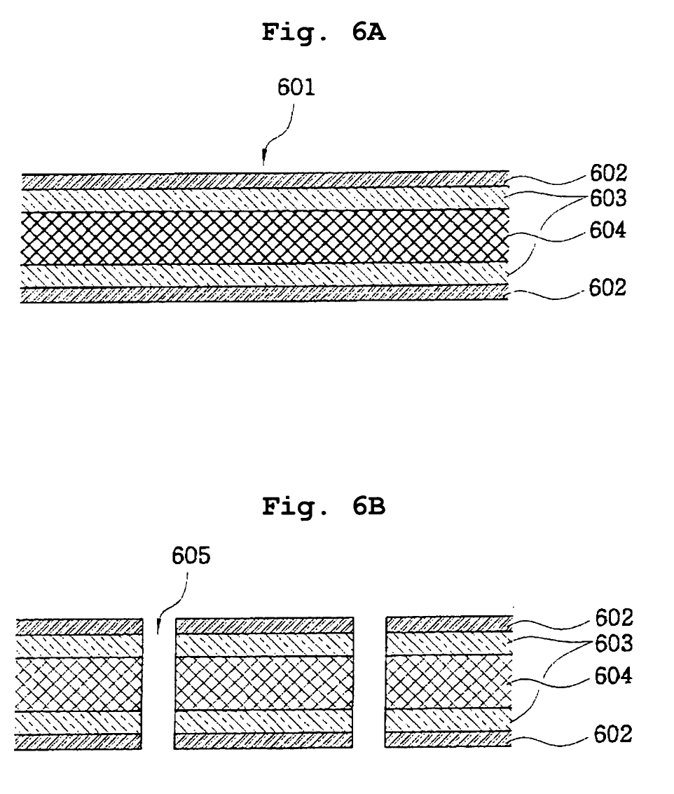

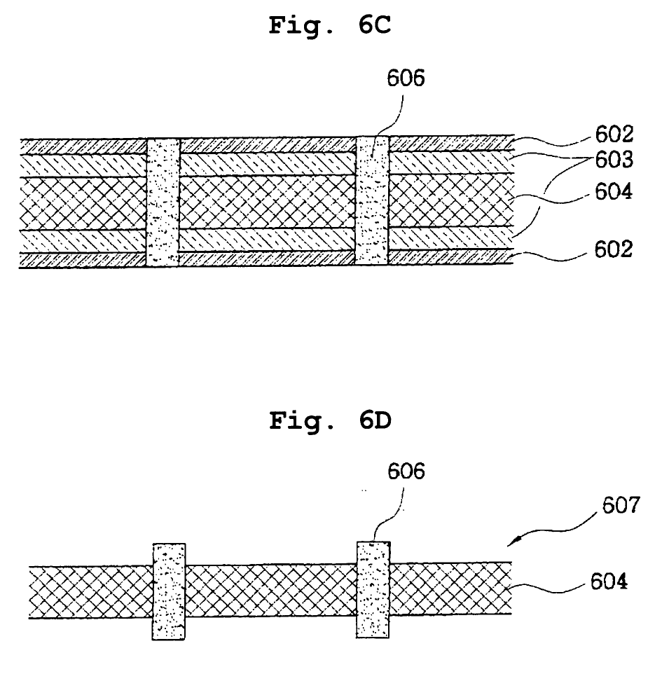

FIGS. 6A to 6D are sectional views stepwisely showing the fabrication of an insulating layer 607 constituting a multi-layered PCB according to another embodiment of the present invention.

The insulating layer 607 according to FIGS. 6A to 6D is different from the insulating layer 506 according to FIGS. 5A to 5D in that the insulating layer does not consist of a single layer, but a completely hardened (c-stage) thermosetting resin layer and semi-hardened (b-stage) thermosetting resin layers attached to both sides of the completely hardened thermosetting resin.

In FIG. 6A, there is illustrated an insulating layer 601. The insulating layer 601 consists of a completely hardened thermosetting resin 604, semi-hardened thermosetting resins 603 attached to both sides of the completely hardened thermosetting resin 604, and release films 602 attached to the semi-hardened thermosetting reins 603.

Meanwhile, the insulating layer consisting of dielectric resin has a higher impedance than the circuit layer. Affecting a circuit pattern, an impedance value of the insulating layer depends on thickness variation of the insulating layer, and physical properties of the dielectric resin, that is, dielectric constant, mass, or volume of the dielectric resin. Therefore, the insulating layer including the semi-hardened thermosetting resin is useful to control the impedance value, and secures excellent plasticity during layering of the insulating layers and the circuit layers.

The insulating layer 601 is drilled to create openings 605 therethrough as shown in FIG. 6B.

The openings 605 thus created are plugged with paste 606 as shown in FIG. 6C, and release films 602 are then removed from the semi-hardened thermosetting resin as shown in FIG. 6D, thereby accomplishing the insulating layer 607.

The insulating layer 607 may be used as one of the insulating layers 607a, 607b of FIG. 7 according to the present invention.

At this time, correct position and pattern of the insulating layers must be precisely planned in advance in consideration of the circuit patterns of the circuit layers layered on the insulating layers. Furthermore, the number of the insulating layers in the multi-layered PCB depends on the total number of layers constituting the multi-layered PCB. For example, the one, two, and three insulating layers are needed in a four-, six-, and eight-layered PCB, respectively. Unlike the present invention, two and four insulating layers are needed in a four- and six-layered PCB, respectively, in a conventional build-up process.

As in FIG. 7, the circuit layers according to FIGS. 2A to 2E, FIGS. 3A to 3D, or FIGS. 4A to 4D, and the insulating layers according to FIGS. 5A to 5D or FIGS. 6A to 6D are alternately layered.

The resulting laminate consisting of the circuit and insulating layers is then subjected to a targeting and a trimming process so as to precisely match the via holes of the circuit layers with the openings of the insulating layers.

The targeting process is defined as a process of drilling the resulting laminate to create target holes on ‘target guide marks’ acting as base points, and a target drill using an X-ray beam is useful in the targeting process.

Furthermore, in the trimming process, the resin and copper foil flowing out of the laminate and then solidified are trimmed to prevent a plurality of laminates from scratching each other and to secure safety.

As shown in FIG. 7, the circuit layers and insulating layers severally formed according to different processes are arranged in such a way that they are alternately layered, and then compressed to make them come into contact with each other to fabricate a six-layered PCB as shown in FIG. 8.

At this time, a hot press is frequently used to compress the circuit and insulating layers to fabricate the multi-layered PCB. In detail, the laminate consisting of the circuit and insulating layers is heat-compressed in a vacuum chamber by hot plates, constituting the hot press, positioned at an upper and a lower part of the vacuum chamber. This is what is called a vacuum hydraulic lamination (VHL) process.

Alternatively, a vacuum press may be used to compress the laminate. At this time, the circuit and insulating layers are layered in a vacuum chamber using an electric heater acting as a heating source while gas is applied into the vacuum chamber to compress the circuit and insulating layers. In this regard, the heat plates are not used to compress the laminate, so different laminates, for example, laminates including six, eight, and ten layers can be compressed at the same time. Therefore, the vacuum press is useful in small scale production of the multi-layered PCB.

According to the conventional build-up process, the multi-layered PCB has a structure that the insulating layer is layered on a double-sided PCB and a single-side PCB is layered on the double-sided PCB. On the other hand, the multi-layered PCB according to the present invention is structured such that a plurality of double-sided PCBs are continuously layered while insulating layers are inserted between the double-sided PCBs.

Therefore, it can be seen by the structure of the multi-layered PCB how to fabricate the multi-layered PCB.

To sum up, great advances in the electronic parts industry based on the development of the electronic industry allows most of the electronic goods to be lightened and slimmed, and to become multipurpose. However, a conventional method of fabricating a PCB has a limit in coping with the recent trend of miniaturization and slimness of the electronic goods, and is insufficiently competitive in terms of fabrication cost when the multipurpose PCB is fabricated according to the conventional method. Meanwhile, currently, the selling price of the electronic parts is dropping, and the great advances in the electronic parts industry contribute to shortening a fabrication period of them.

With respect to the above recent trend, a conventional method of fabricating a MLB using the build-up process is disadvantageous in that when the number of layers constituting the MLB is increased, the procedure of creating via holes using the laser beam, the layering procedure of the layers, and the plating procedure are sequentially repeated to prolong fabrication time of the MLB, and it is difficult to inspect the MLB during the fabrication of the desired MLB, thus undesirably increasing the defective proportion of the MLB to increase fabrication cost of the MLB.

On the other hand, the present invention provides a method of fabricating the MLB capable of avoiding the disadvantages, in which the plugging process of the via holes using paste may be omitted because a copper clad laminate is plated with copper and the via holes are plugged with copper after they are created by drilling.

Additionally, the conventional method of fabricating the MLB has the low degree of freedom during designing the via holes because of restrictions inherent in the fabrication process of the MLB. On the other hand, the method according to the present invention is advantageous in that the limit of the conventional method is overcome, a length of the circuit pattern is shortened, and the selective interlayer through connection is feasible, thereby reducing area and the number of layers of the MLB.

Furthermore, the present invention has an advantage in that the copper clad laminate is drilled in such a way that a diameter of each via hole is relatively small and then plated with copper to plug the fine via holes with copper, thereby omitting the plugging process of the via holes using paste to simplify the method of fabricating the MLB.

Moreover, in the present invention, the insulating layers including semi-hardened resin are attached to both sides of completely hardened resin, thus reducing the effect of impedance of the insulating layer to the circuit pattern and securing excellent plasticity during layering of the insulating and circuit layers.

The present invention has been described in an illustrative manner, and it is to be understood that the terminology used is intended to be in the nature of description rather than of limitation. Many modifications and variations of the present invention are possible in light of the above teachings. Therefore, it is to be understood that within the scope of the appended claims, the invention may be practiced otherwise than as specifically described.

What is claimed is:

1. A method of fabricating a multi-layered printed circuit board, comprising:
forming a plurality of circuit layers;
forming insulating layers before or after the circuit layers are formed; and
alternately layering the circuit layers and the insulating layers, and compressing the circuit layers and the insulating layers together.

2. The method as set forth in claim 1, wherein the forming of the circuit layers comprises:
creating via holes through a copper clad laminate;
copper-plating the copper clad laminate and walls of the via holes; and
constructing a circuit pattern on the copper clad laminate,
whereby said circuit layers are double-sided printed circuit boards.

3. The method as set forth in claim 2, further comprising plugging paste in the via holes after the copper clad laminate and the walls of the via holes are plated with copper.

4. The method as set forth in claim 1, wherein the forming of the circuit layers comprises:
creating via holes through a copper clad laminate;
copper-plating the copper clad laminate and walls of the via holes to plug copper in the via holes; and
constructing a circuit pattern on the copper clad laminate,
whereby said circuit layers are double-sided printed circuit boards.

5. The method as set forth in claim 4, wherein the via holes each have a diameter of 50 to 100 μm.

6. The method as set forth in claim 1, wherein the forming of the circuit layers comprises:
creating via holes through a copper clad laminate;
copper-plating the copper clad laminate and walls of the via holes;
plugging conductive paste in the via holes; and
constructing a circuit pattern on the copper clad laminate,
whereby said circuit layers are double-sided printed circuit boards.

7. The method as set forth in claim 1, wherein the forming of the insulating layers comprises:
creating openings through an insulating layer attached by release films;
plugging paste in the openings; and
removing the release films from the insulating layer.

8. The method as set forth in claim 7, wherein the insulating layer includes a completely hardened (c-stage) resin layer and semi-hardened (b-stage) resin layers attached to both sides of the completely hardened resin layer.

9. The method as set forth in claim 1, wherein layering the circuit layers and insulating layers is subject to a targeting and a trimming process for precisely matching the via holes of the circuit layers with the openings of the insulating layers.

10. The method as set forth in claim 9, wherein the targeting process comprising of drilling the laminate to create target holes using a x-ray beam, and the trimming process comprising of solidifying the resin and the copper foil flowing out of the laminate and trimming.

11. The method as set forth in claim 1, in which a hot press is used to compress the circuit and insulating layers to fabricate the multi-layered PCB.

12. The method as set forth in claim 1, in which a vacuum press is used to compress the laminate in a vacuum chamber using an electric heater.
